(19) United States
(12) Patent Application Publication
(10) Pub. No.: US 2013/0285157 A1
(43) Pub. Date: Oct. 31, 2013

(54) SEMICONDUCTOR STRUCTURE AND METHOD FOR MANUFACTURING THE SAME

(71) Applicants: Haizhou Yin, Poughkeepsie, NY (US); Zhijiong Luo, Poughkeepsie, NY (US); Huilong Zhu, Poughkeepsie, NY (US)

(72) Inventors: Haizhou Yin, Poughkeepsie, NY (US); Zhijiong Luo, Poughkeepsie, NY (US); Huilong Zhu, Poughkeepsie, NY (US)

(73) Assignee: INSTITUTE OF MICROELECTRONICS, CHINESE ACADEMY OF SCIENCES, Beijing (CN)

(21) Appl. No.: 13/988,192

(22) PCT Filed: Feb. 26, 2011
(86) PCT No.: PCT/CN2011/071343

§ 371 Date: Jun. 28, 2013

(30) Foreign Application Priority Data
Nov. 18, 2010 (CN) 201010551454.X

(51) Int. Cl. H01L 29/40; H01L 27/088

(52) U.S. Cl. CPC H01L 29/401; H01L 27/088
USPC 257/401; 438/279

(57) ABSTRACT

A semiconductor structure comprises: a first interlayer structure having a first dielectric layer and first contact vias; a second interlayer structure having a cap layer and second contact vias; and a third interlayer structure having a second dielectric layer and third contact vias. The first dielectric layer is flush with a gate stack or covers the gate stack, and the first contact vias penetrate through the first dielectric layer and are electrically connected with at least a portion of source/drain regions. The cap layer covers the first interlayer structure, and the second contact vias penetrate through the cap layer and are electrically connected with the first contact vias and the gate stack through a first liner. The second dielectric layer covers the second interlayer structure, and the third contact vias penetrate through the second dielectric layer and are electrically connected with the second contact vias through a second liner.

### CROSS REFERENCE TO RELATED APPLICATION

This application is a U.S. National Stage Application under 35 U.S.C. §371 of International Application No. PCT/CN2011/071343, filed on Feb. 26, 2011, entitled “SEMICONDUCTOR STRUCTURE AND METHOD FOR MANUFACTURING THE SAME”, which claimed priority to Chinese Application No. 201010551454.X, filed on Nov. 18, 2010, all of which are hereby incorporated by reference in their entirety. The International Application was published in Chinese on May 24, 2012 as International Publication No. WO/2012/065377 under PCT Article 21(2)

### FIELD OF THE INVENTION

The present invention relates to the technical field of semiconductor manufacturing, and specifically, to a semiconductor structure and a method for manufacturing the same.

### BACKGROUND OF THE INVENTION

With the development of semiconductor manufacturing technology, integrated circuits with higher performance and more powerful functions require greater element density. Thus, sizes of elements and spacing among elements need to be further scaled down (which has entered the nanometer level now). With the sizes of semiconductor elements being scaled down, various microeffects have emerged accordingly. In order to satisfy requirements in element development, persons skilled in the art have been devoting to exploring new manufacturing processes.

In order to solve aforesaid problem, patent application US2009/032194A1 has proposed a method for forming through holes (see FIG. 29), comprising: etching a first dielectric layer to form a plurality of first through holes, filling the first through holes with a metal to form a first layer of contact metal 121 in contact with source/drain regions; then covering a gate 104 and the first layer of contact metal 121 with a gate etch stop layer 124 and a second dielectric layer 126; performing a second etching to form a plurality of second through holes, which penetrate through both the gate etch stop layer 124 and the second dielectric layer 126 and also exposes the first contact vias 121; and then filling the second through holes to form a plurality of second contact vias 128.

However, aforesaid second dielectric layer 126 is rather thick, and thus a rather large area has to be reserved in etching the second through holes. Consequently, the cross-sectional area of the formed second through holes may be rather large, which is not favorable for saving areas.

### SUMMARY OF THE INVENTION

The present invention aims to provide a semiconductor structure and a method for manufacturing the same, which are favorable for saving area and forming more elements on the same area, thereby improving integration density of a semiconductor structure.

In one aspect, the present invention provides a method for manufacturing a semiconductor structure, comprising:
a) forming at least one gate stack and respective source/drain regions on a substrate, wherein the source/drain regions are located at both sides of the gate stack and are embedded in the substrate;
b) forming a first interlayer structure which comprises a first dielectric layer and a plurality of first contact vias, wherein the first dielectric layer is flushed with the gate stack or covers the gate stack, and the first contact vias penetrate through the first dielectric layer and are electrically connected with at least a portion of respective source/drain regions;
c) forming a second interlayer dielectric layer which comprises a cap layer and a plurality of second contact vias, wherein the cap layer covers the first interlayer structure, and the second contact vias penetrate through the cap layer and are electrically connected with respective first contact vias and gate stacks; and
d) forming a third interlayer structure which comprises a second dielectric layer and a plurality of third contact vias, wherein the second dielectric layer covers the second interlayer structure, and the third contact vias penetrate through the second dielectric layer and are electrically connected with the second contact vias.

Accordingly, the present invention further provides a semiconductor structure comprising:

At least one gate stack which is formed on a substrate;

source/drain regions located at both sides of the gate stack and embedded in the substrate;

a first interlayer structure which comprises a first dielectric layer and a plurality of first contact vias, wherein the first dielectric layer is flushed with the gate stack or covers the gate stack, and the first contact vias penetrate through the first dielectric layer and are electrically connected with at least a portion of respective source/drain regions;

a second interlayer structure which comprises a cap layer and a plurality of second contact vias, wherein the cap layer covers the first interlayer structure, and the second contact vias penetrate through the cap layer and are electrically connected with the first contact vias and gate stacks;

a third interlayer structure which comprises a second dielectric layer and a plurality of third contact vias, wherein the second dielectric layer covers the second interlayer structure, and the third contact vias penetrate through the second dielectric layer and are electrically connected with respective second contact vias through a second liner.

The present invention further provides a semiconductor structure comprising:

At least one gate stack which is formed on a substrate;

source/drain regions located at both sides of the gate stack and embedded in the substrate;

a first interlayer structure which comprises a first dielectric layer and a plurality of first contact vias, wherein the first dielectric layer is flushed with the gate stack or covers the gate stack, and the first contact vias penetrate through the first dielectric layer and are electrically connected with at least a portion of respective source/drain regions;

a second interlayer structure which comprises a cap layer and a plurality of second contact vias, wherein the cap layer covers the first interlayer structure, and the second contact vias penetrate through the cap layer and are electrically connected with respective first contact vias and gate stacks;

a third interlayer structure which comprises a second dielectric layer and a plurality of third contact vias, wherein the second dielectric layer covers the second interlayer structure, and the third contact vias penetrate through the second dielectric layer and are electrically connected with respective second contact vias, and the cross-sectional area of the second contact vias is smaller than the cross-sectional area of the first contact vias and/or the cross-sectional area of the third contact vias.

The present invention further provides a method for manufacturing a semiconductor structure, comprising:
a) forming at least one gate stack and source/drain regions on a substrate, wherein the source/drain regions are located at both sides of the gate stack and are embedded in the substrate;
b) forming a first interlayer structure which comprises a first dielectric layer and a plurality of first contact vias, wherein the first dielectric layer is flushed with the gate stack or covers the gate stack, and the first contact vias penetrate through the first dielectric layer and are electrically connected with at least a portion of the source/drain regions; and
c) forming a fourth interlayer structure which comprises a cap layer, a second dielectric layer and a plurality of fourth contact vias, wherein the cap layer covers the first interlayer structure, the second dielectric layer covers the cap layer, and the fourth contact vias penetrate through the cap layer and the second dielectric layer and are electrically connected with respective first contact vias and gate stacks, and at the interface between the cap layer and the second dielectric layer, the cross-sectional area of the fourth contact vias embedded within the cap layer is smaller than the cross-sectional area of the first contact vias and/or the cross-sectional area of the fourth contact vias embedded within the second dielectric layer.

The present invention further provides a semiconductor structure comprising:

At least one gate stack and source/drain regions, wherein the gate stack is formed on a substrate, and the source/drain regions are located at both sides of the gate stack and are embedded in the substrate;

a first interlayer structure which comprises a first dielectric layer and a plurality of first contact vias, wherein the first dielectric layer is flushed with the gate stack or covers the gate stack, and the first contact vias penetrate through the first dielectric layer and are electrically connected with at least a portion of respective source/drain regions; and

a fourth interlayer structure which comprises a cap layer, a second dielectric layer and a plurality of fourth contact vias, wherein the cap layer covers the first interlayer structure, the second dielectric layer covers the cap layer, and the fourth contact vias penetrate through the cap layer and the second dielectric layer and are electrically connected with the first contact vias and the gate stack; at the interface between the cap layer and the second dielectric layer, the cross-sectional area of the fourth contact vias embedded within the cap layer is smaller than the cross-sectional area of the first contact vias and/or the cross-sectional area of the fourth contact vias embedded within the second dielectric layer.

As compared to the prior art, the implementation of the technical solutions provided by the present invention exhibits the following advantages.

The step for filling the second through holes to form contact vias has two stages: a plurality of second contact vias are firstly formed in a cap layer, and then a plurality of third contact vias are formed in a second dielectric layer, such that, for contact vias with a certain thickness, the thickness of the dielectric layer (e.g. the cap layer or the second dielectric layer), which needs to be etched when forming corresponding through holes at formation of each part, is reduced, such that the process window for forming through holes becomes smaller, thereby saving areas and improving integration density of a semiconductor structure. Besides, since the thickness of the cap layer is smaller than the thickness of the dielectric layer for carrying the second through holes, during the process of forming the second contact vias in contact with a gate stack, the thickness of the dielectric layer etched at formation of desired through holes is reduced, which is favorable for controlling the etching process and diminishing damage to the gate stack. Further, at formation of the third contact vias, the second contact vias instead of the gate stack serve as a stop layer, which also further reduces damages to the gate stack. Additionally, the step for filling the second through holes to form contact vias has two stages: the second contact vias are firstly formed in a cap layer and then the third contact vias are formed in a second dielectric layer, such that wiring connections having the same interconnect effect are now formed in two layers of dielectric layers (e.g. the cap layer and the second dielectric layer) instead of being formed in one layer of dielectric layer (e.g. the dielectric layer comprising the second through holes in the prior art), which is favorable for the process design.

It is favorable for extending the process window during the process of forming the second contact vias, by way of making the cross-sectional area of the second contact vias smaller than the cross-sectional area of the first contact vias and/or the cross-sectional area of the third contact vias (e.g. making the cross-sectional area of the second contact vias smaller than the opening size of the contact vias). Even if the formed second contact vias deviates relatively far from intended positions of the product design, it is not prone to cause short circuits between the gate stack and the source/drain regions.

As stated above, since the process window needed at formation of the through holes becomes smaller, the distance between the second contact vias electrically connected with the gate stack and the second contact vias electrically connected with the first contact vias may be further shortened, which makes it applicable that the second contact vias electrically connected with the gate stack may not be formed on an isolation region of the substrate. Instead, it may be formed on an active region of the substrate, which is favorable for diminishing the distance between the neighboring elements and therefore further improving the integration density of a semiconductor structure.

Since a portion of the second contact vias electrically connected with the first contact vias is formed on an isolation region of the substrate, the second contact vias shall be further able to reduce the contact resistance ascribing to its portion formed on the isolation region of the substrate, when they are electrically connected with the first contact vias (i.e. electrically connected with an active region of the substrate) in a small area (i.e. the remaining portion of the second contact vias).

Besides, the step for forming a plurality of contact vias is altered to form a plurality of second contact vias first and then to form a plurality of third contact vias such that, for contact vias with a certain thickness, the thickness of the dielectric layer (e.g. the cap layer or the second dielectric layer), which needs to be etched at formation of each part, is reduced; for second contact vias and third contact vias with a certain opening size, the decrease of their depth-to-width ratios is favorable for improving the filling effect of filling corresponding through holes to form the second contact vias and the third contact vias; accordingly, the shape of the vertical cross-sections of the second contact vias and the third contact vias will no longer be confined to be conical but may be extended to be other shape such as a square, which furthermore makes it possible to increase cross-sectional areas of the second contact vias and the third contact vias, so as to reduce the contact resistance.

The step for filling a plurality of second through holes to form a plurality of contact vias is divided into two parts, namely, a plurality of fourth contact vias embedded into a cap layer and a second dielectric layer are formed; for a plurality of contact vias with a certain thickness, during the formation of each part, the thickness of the dielectric layer (e.g. the cap layer or the second dielectric layer), which needs to be etched when forming corresponding through holes, is reduced, such that the process window needed at formation of the through holes becomes smaller, which therefore saves area and improves the integration density of a semiconductor structure; besides, since the thickness of the cap layer is smaller than the thickness of the dielectric layer comprising the second through holes, thus during the process of forming fourth contact vias embedded in the cap layer and connected with the gate stack, the thickness of the dielectric layer etched at formation of desired through holes is reduced, which is favorable for controlling the etching process and diminishing damage to the gate stack; further, at formation of the through holes embedded in the second dielectric layer, the cap layer instead of the gate stack is served as a stop layer, which thus further reduces damage to the gate stack.

It is favorable for extending the process window at formation of the fourth contact vias, by way of making the cross-sectional area of the fourth contact vias formed in the cap layer smaller than the cross-sectional area of the first contact vias and/or the cross-sectional area of the fourth contact vias formed in the second dielectric layer (e.g. making the cross-sectional area of the fourth contact vias formed in the cap layer smaller than the opening size of the contact vias); namely, even if the formed fourth contact vias deviates relatively far from intended positions of the product design, it is not prone to cause short circuits between the gate stack and the source/drain regions.

As stated above, since the process window needed at formation of the through holes becomes smaller, thus the distance between the fourth contact vias electrically connected with the gate stack and the fourth contact vias electrically connected with the first contact vias may be further shortened, which makes it applicable that the second contact vias electrically connected with the gate stack needs no longer to be formed on an isolation region of the substrate, instead, it may be formed on an active region of the substrate, which is favorable for diminishing the distance between neighboring elements and therefore further improving the integration density of a semiconductor structure.

Additionally, the step for filling the second through holes to form a plurality of contact vias is divided into two parts, namely, a plurality of fourth contact vias embedded in a cap layer and a second dielectric layer are formed such that, for contact vias with a certain thickness, during the process of forming each part, the thickness of a dielectric layer (e.g. the cap layer or the second dielectric layer) which needs to be etched is reduced; as for the fourth contact vias with a certain opening size embedded in the cap layer and the fourth contact vias embedded in the second dielectric layer, the decrease of their depth-to-width ratios is favorable for improving the filling effect of filling corresponding through holes to form the fourth contact vias; accordingly, the shape of the vertical cross-sections of the fourth contact vias embedded in the cap layer and the fourth contact vias embedded in the second dielectric layer will no longer be confined to be conical but may be extended to be other shape such as a square, which furthermore make it possible to increase cross-sectional areas of the fourth contact vias, so as to reduce the contact resistance.

### BRIEF DESCRIPTION OF THE DRAWINGS

Other characteristics, objectives and advantages of the present invention are made more evident according to the following detailed description of exemplary embodiment(s) and the accompanying drawings.

FIG. 1 illustrates a flowchart of a method for manufacturing a semiconductor structure according to an embodiment of the present invention;

FIG. 2 to FIG. 7, FIG. 9, FIG. 10 and FIG. 12 illustrate cross-sectional views at respective stages of manufacturing a semiconductor structure according to an embodiment of the present invention in view of the flowchart shown in FIG. 1;

FIG. 8 and FIG. 11 illustrate top views of respective semiconductor structures shown in FIG. 7 and FIG. 10;

FIG. 13 illustrates a top view at formation of second contact vias during the process of manufacturing a semiconductor structure according to a preferred embodiment of the present invention in view of the flowchart shown in FIG. 1;

FIGS. 14 and 15 illustrate cross-sectional views of the semiconductor structure shown in FIG. 13 along C-C and D-D directions, respectively;

FIG. 16 illustrates a top view at formation of third contact vias during the process of manufacturing a semiconductor structure shown in FIG. 13;

FIG. 17 and FIG. 18 illustrate cross-sectional views of a semiconductor structure shown in FIG. 16 along E-E and F-F directions, respectively;

FIG. 19 and FIG. 20 illustrate cross-sectional views of the semiconductor structure shown in FIG. 16 along E-E and F-F directions after the third through holes are filled to form a plurality of third contact vias;

FIG. 21 illustrates a top view of a semiconductor structure at formation of second contact vias during the process of manufacturing a semiconductor structure according to another preferred embodiment of the present invention in view of the flowchart shown in FIG. 1;

FIG. 22 illustrates a cross-sectional view of the semiconductor structure shown in FIG. 21 along G-G direction;

FIG. 23 illustrates a cross-sectional view of the semiconductor structure along G-G direction after the third through holes is filled to form a plurality of third contact vias;

FIG. 24 to FIG. 26 illustrate cross-sectional views at respective stages of a method for manufacturing a semiconductor structure according to an embodiment of the present invention;

FIGS. 27 and 28 illustrate top views of fourth contact vias in various arrangements in semiconductor structures according to embodiments of the present invention; and

FIG. 29 illustrates a cross-sectional view of a semiconductor structure in the prior art.

### DETAILED DESCRIPTION OF THE INVENTION

In order to make the objectives, technical solutions and advantages of the present invention more apparent, specific exemplary embodiments thereof are described in detail in conjunction with the accompanying drawings.

Embodiments of the present invention are described here below in detail, and the examples of the embodiments are illustrated in the accompanying drawings. To simplify the disclosure of the present invention, description of the components and arrangements of specific examples is given. Of course, they are only illustrative and are not intended to limit the present invention. Moreover, in the present invention, reference number(s) and/or letter(s) may be repeated in different embodiments. Such repetition is for the purposes of simplification and clearness, and does not denote the relationship between respective embodiments and/or arrangements being discussed. In addition, the present invention provides various examples for specific processes and materials. However, it is obvious for a person of ordinary skill in the art that other processes and/or materials may alternatively be utilized.

Since the semiconductor structures provided by the present invention may be practiced in several preferred structures, the preferred structures are described individually here below.

### First Embodiment

Reference is made to FIG. 10 to FIG. 12. A semiconductor structure comprises a substrate 100, a gate stack, sidewall spacers 230 (In this disclosure, the illustrated semiconductor structures comprises sidewall spacers 230, but the semiconductor structures may not comprise sidewall spacers 230 in other embodiments), a first dielectric layer 300, first contact vias 320, a cap layer 400, second contact vias 420, a second dielectric layer 500, third contact vias 520 and respective liners (e.g. a metal liner, a first liner and a second liner which are not shown); wherein the source/drain regions 110 are formed within the substrate 100; the gate stack is formed on the substrate 100, and the sidewall spacers 230 are formed at the sidewalls of the gate stack; the first dielectric layer 300 covers the source/drain regions 110, the cap layer 400 covers the gate stack and the first dielectric layer 300, and the first contact vias 320 which penetrate through the first dielectric layer 300 are electrically connected with the source/drain regions 110, and a metal liner is formed between the first contact vias 320 and the source/drain regions 110; the first contact vias 320 are electrically connected with the second contact vias 420, which penetrate through the cap layer 400, through a first liner; and/or, the second contact vias 420 are electrically connected with a gate metal 210 in the gate stack through the first liner; the first dielectric layer 300 and the first contact vias 320 are referred to as a first interlayer structure, and the cap layer 400 and the second contact vias 420 are referred to as a second interlayer structure; the second dielectric layer 500 covers the cap layer 400 and the second contact vias 420; the third contact vias 520 which penetrate through the second dielectric layer 500 are electrically connected with the second contact vias 420 through a second liner (the materials of the metal liner, the first liner and the second liner all may be Ti, TiN, Ta, TaN, Ru or their combinations); and the second dielectric layer 500 and the third contact vias 520 are referred to as a third interlayer structure. The first dielectric layer 300, the first contact vias 320, the cap layer 400, the second contact vias 420, the second dielectric layer 500 and the third contact vias may have multi-layer structures, respectively.

The sidewalls of the second contact vias 420 or the third contact vias 520 may be perpendicular to the top surface of the substrate 100 (the term “perpendicular” means that the deviation of the angles between the sidewalls and the top surface of the substrate 100 from 90 degree is in a range of a permitted processing error). As such, for the second contact vias 420 and the third contact vias 520 with a certain opening size, the decrease of depth-to-width ratios is favorable for improving the filling effect of filling corresponding through holes to form the second contact vias 420 and the third contact vias 520; accordingly, the shape of the vertical cross-sections of the second contact vias 420 and the third contact vias 520 will no longer be confined to be conical, but may be other shapes such as a square, which furthermore makes it possible to increase the cross-sectional areas of the second contact vias 420 and the third contact vias 520, thereby reducing the contact resistance.

The gate stack comprises a gate (e.g. a gate metal 210) and a gate dielectric layer 220; preferably, the top surface of the gate stack and the top surface of the first contact vias 320 are flushed with the top surface of the first dielectric layer 300 (herein, the term “at the same level” or “in the same plane” means that the difference between the heights of two structures is in a range of a permitted processing error); the materials of the first dielectric layer 300 and the second dielectric layer 500 may be the same as or different from the material of the cap layer 400, and the material of the cap layer 400 is an insulating material. The material of the first dielectric layer 300 may comprise a doped or undoped silicon glass, for example, FSG, BPSG, PSG, UGS, SiON, a low-k material or their combinations (for example, the first dielectric layer 300 may be in a multi-layer structure, wherein neighboring layers are made of different materials). The materials for the cap layer 400 and the second dielectric layer 500 may be selected from the same group of materials as that for the first dielectric layer 300, and are omitted herein.

The cross-sectional area of the first contact vias 320 and/or the cross-sectional area of the third contact vias 520 may be equal to or greater than the cross-sectional area of the second contact vias 420. It is favorable for extending the process window at formation of second contact vias 420 by way of making the cross-sectional area of the second contact vias 420 smaller than the cross-sectional area of the first contact vias 320 and/or the cross-sectional area of the third contact vias 520 (e.g. the cross-sectional area of the second contact vias 420 is smaller than the opening size of the contact vias). Namely, even if the formed second contact vias 420 deviates relatively far from intended positions of the product design, it is not prone to cause short circuits between the gate stack and the source/drain regions 110.

Optionally, the semiconductor structure further comprises a contact layer 120, which is formed only between the first contact vias 320 and the exposed source/drain regions 110 in the substrate 100.

Preferably, the thickness of the cap layer 400 is smaller than half of the thickness of the second dielectric layer 500. For example, the thickness of the cap layer 400 is smaller than 30 nm, while the thickness of the second dielectric layer 500 is greater than 50 nm. The decrease in thickness of the cap layer 400 is favorable for controlling the etching process corresponding to formation of second contact vias embedded in the cap layer 400, so as to reduce damage to the gate metal 210 and/or the first contact vias 320.

In the semiconductor structure, at least one of the second contact vias 420 is positioned on an active region of the substrate 100. However, in view of the manufacturing requirements, it is also applicable that when a certain second contact via 420 is formed, a portion thereof is formed on an isolation region of the substrate 100. Preferably, the second contact vias 420 connected with the gate stack are formed on an active region of the substrate 100, and it is advantageous for such a structure to shorten the distance between neighboring elements, and to save area so as to further improve the integration density of a semiconductor structure. Besides, portions of the second contact vias 420 connected with the first contact vias 320 may be formed on an isolation region of the substrate 100, such that when the second contact vias 420 are electrically connected with the first contact vias 320 (i.e. electrically connected with the source/drain regions 110 of the substrate 100) in a relatively small area (i.e, the remaining portion of the second contact vias 420), it is able to further reduce the contact resistance ascribing to their portions formed on the isolation region of the substrate 100.

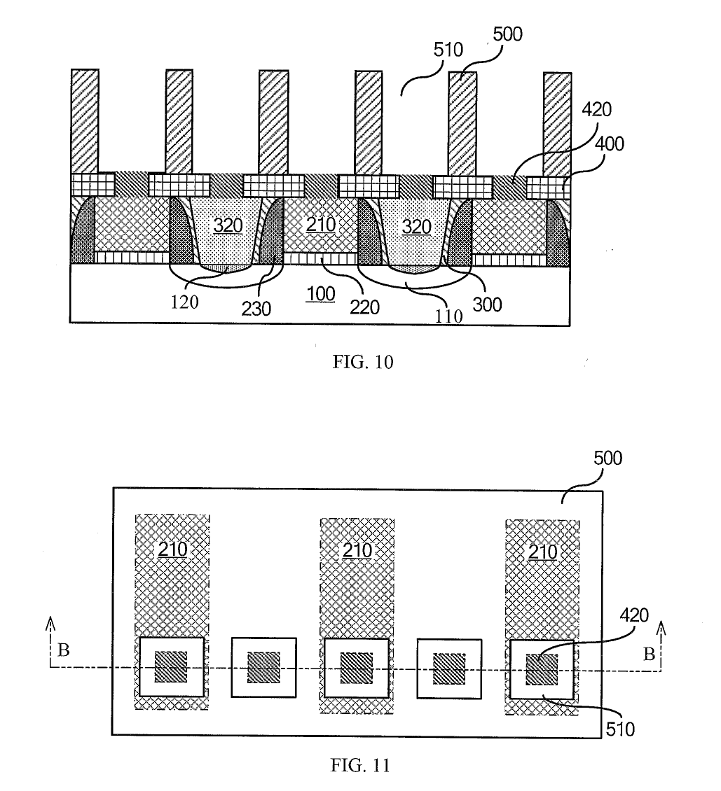

With reference to FIG. 11, it is apparent that the second contact vias 420 may be located substantially in line (i.e. the third through holes 510 and third contact vias 520 may also be located substantially in line). In other embodiments, the positions for forming second contact vias 420 may be arranged in other manners, which may be referred to from description of the Second Embodiment.

### Second Embodiment

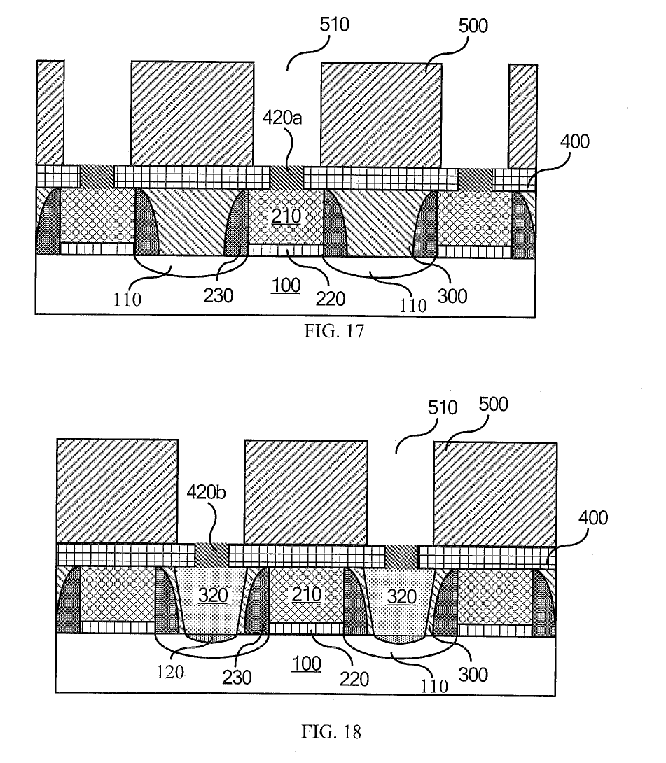

With reference to the description of the same part in the First Embodiment, and with further reference to FIG. 16 to FIG. 20, the second contact vias 420 may be classified into two categories. One refers to as second contact vias 420a electrically connected with a gate metal 210 of a gate stack, and the other refers to as second contact vias 420b electrically connected with first contact vias 320. As shown in FIG. 16, the second contact vias 420a are not aligned with two neighboring second contact vias 420b. With reference to FIG. 17 to FIG. 20, one or more second contact vias(s) 420 electrically connected with the gate metal 210 on the semiconductor structure is/are not aligned with the two neighboring contact vias 420b electrically connected with the source/drain regions 110, which noticeably differs the Second Embodiment from the First Embodiment, and such an arrangement has the advantage to enable the second contact vias 420a to be away from the second contact vias 420b as far as possible, so as to facilitate subsequent processes and to restrain short circuits occurring between the source/drain regions and the gate, which further reduces the capacitance between the gate and the source/the drain, and further enhances the performance of a semiconductor structure. However, as compared with the prior art, the distance between the second contact vias 420 electrically connected with the gate metals 210 and the distance between the second contact vias 420 electrically connected with the first contact vias 320 may be shortened, such that the second contact vias electrically connected with the gate stack shall no longer be formed on an isolation region of the substrate, but may be formed on an active region of the substrate, which is favorable for shortening the distance between the neighboring elements so as to further improve the integration density of a semiconductor structure.

The present invention further provides another semiconductor structure with second contact vias 420 which is different from those in both the First Embodiment and the Second Embodiment, and is described below in the Third Embodiment.

### Third Embodiment

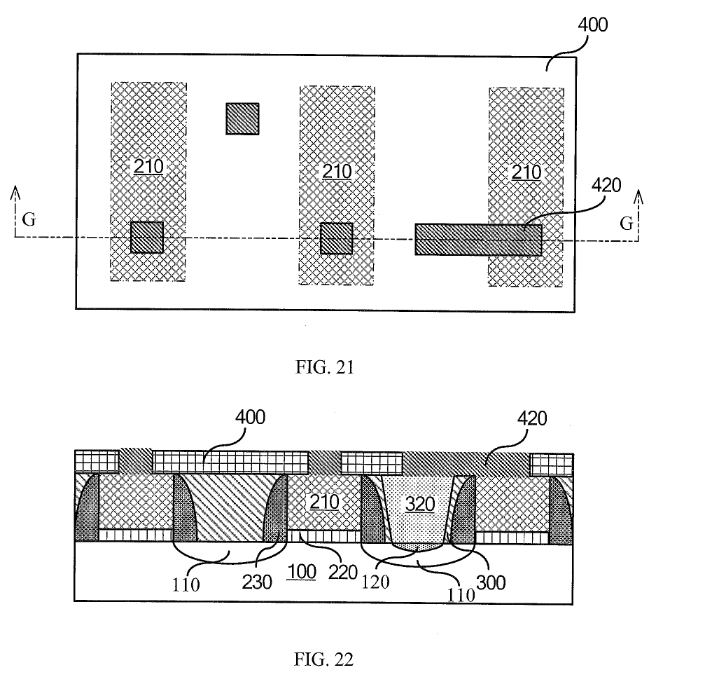

With reference to the description of the same part in the First Embodiment or the Second Embodiment, and further with reference to FIG. 21 to FIG. 23, in certain circumstances, a gate of a semiconductor structure has to be electrically connected with source/drain thereof, or alternatively, a gate or source/drain of a semiconductor structure may be electrically connect with a gate or source/drain of a neighboring semiconductor structure. Such a metal interconnect may be realized locally in a cap layer 400. For example, a gate may be electrically connect with source/drain according to the design requirements, as shown in FIG. 22. And the size and the shape of a second contact via 420 in the cap layer 400 may be adjusted such that it are electrically connected both with a first contact via 320 connected with a source/drain region 110 and with a gate metal 210. The advantage of arranging the second contact via 420 in this way lies in that electrical connection between the gate metal 210 and the first contact via 320 shall be established by controlling the size and the shape of the second contact via 420, so as to realize local connection between the gate and the source/drain. Likewise, local electrical connection between neighboring source/drain regions 110 may be realized by way of arranging one second contact via 420 to be electrically connected with two or more first contact vias 320. The advantage of the embodiment lies in that it is capable of establishing local electrical connection between gates or between a source and a drain, and between a gate and source/drain without using an extra metal interconnect layer, which therefore alleviates the difficulty in metal wiring. Namely, wiring connections having the same interconnect effect are now formed in two layers of dielectric layers (e.g. the cap layer 400 and the second dielectric layer 500) instead of being formed in one layer of dielectric layer (e.g. the dielectric layer comprising the second through holes in the prior art), which is favorable for the process design.

It may be noted that in one semiconductor structure, it may comprise any one or combinations of foregoing embodiments in view of manufacturing requirements. The first contact vias 320 may comprise a material selected from a group consisting of W, Al and TiAl, or combinations thereof (the term “combination” includes compound(s) of abovementioned metals formed by means of multi-target sputtering and the layered structure(s) formed from stacking aforesaid metal layers sequentially, which still refers to the same in the following and thus is omitted herein); and both the second contact vias 420 and the third contact vias 520 may comprise a material selected from a group consisting of W, Cu, Al and TiAl, or combinations thereof.

Particularly, the semiconductor structure further comprises a plurality of first vias and a first metal wiring layer; the first vias are formed between the third contact vias 520 and the first metal wiring layer (metal 1); the first vias or the first metal wiring layer are electrically connected with the third contact vias 520 through a third liner. Both the first vias and the first metal wiring layer may comprise a material selected from a group consisting of W, Cu, Al and TiAl, or combinations thereof. The material and the formation method of the third liner are the same as the materials and formation methods of the first liner and the second liner, and thus are omitted herein.

And/or, the first vias are electrically connected with the third contact vias 520; and on the interface between the first vias and the third contact vias 520, the cross-sectional area of the first vias is smaller than the cross-sectional area of the third contact vias 520. Meanwhile, both the first vias and the first metal wiring layer may comprise Al or TiAl.

The present invention further provides a semiconductor structure, as shown in FIG. 12. The semiconductor structure comprises: a gate stack which is formed on a substrate 100; source/drain regions 110 located at both sides of the gate stack and embedded in the substrate 100; a first interlayer structure which comprises a first dielectric layer 300 and a plurality of first contact vias 320, wherein the first dielectric layer 300 is flushed with the gate stack or covers the gate stack, and the first contact vias 320 penetrate through the first dielectric layer 300 and are electrically connected with at least a portion of the source/drain regions 110; a second interlayer structure which comprises a cap layer 400 and a plurality of second contact vias 420, wherein the cap layer covers the first interlayer structure, and the second contact vias 420 penetrate through the cap layer 400 and are electrically connected with the first contact vias 320 and the gate stack; and a third interlayer structure which comprises a second dielectric layer 500 and a plurality of third contact vias 520, wherein the second dielectric layer 500 covers the second interlayer structure, and the third contact vias 520 penetrate through the second dielectric layer 500 and are electrically connected with the second contact vias 420, and wherein the cross-sectional area of the second contact vias 420 is smaller than the cross-sectional area of the first contact vias 320 and/or the cross-sectional area of the third contact vias 520.

The semiconductor structure may further comprise a contact layer (e.g. a metal silicide layer 120), which is formed only between the source/drain regions 110 and the first contact vias 320. Particularly, at least one of the second contact vias 420 electrically connected with the gate stack is not aligned with its neighboring second contact vias 420 electrically connected with the first contact vias 320.

Optionally, the second contact vias 420 electrically connected with the gate stack is formed on an active region of the substrate 100; and/or, portions of the second contact vias 420 electrically connected with the first contact vias 320 are formed on an isolation region of the substrate 100.

The sidewalls of the second contact vias 420 or of the third contact vias 520 may be perpendicular to the top surface of the substrate 100. The thickness of the cap layer 400 may be smaller than half of the thickness of the second dielectric layer 500. The material of the cap layer 400 is different from the materials of the first dielectric layer 300 and the second dielectric layer 500, and the material of the cap layer is an insulating material. The thickness of the cap layer is smaller than 30 nm; and/or, the thickness of the second dielectric layer 500 is greater than 50 nm.

In the present embodiment, the materials and formation methods of the first dielectric layer 300, the cap layer 400 and the second dielectric layer 500 as well as the first contact vias 320, the second contact vias 420 and the third contact vias 520 are the same as those provided in aforesaid embodiments; and the materials and formation methods of the gate stack, the source/drain regions 110 and the contact layer (e.g. a metal silicide layer) may be formed according to known or conventional methods in the art, and thus are omitted herein.

Aforesaid embodiments are to be further described here below in view of the method for manufacturing a semiconductor structure provided by the present invention.

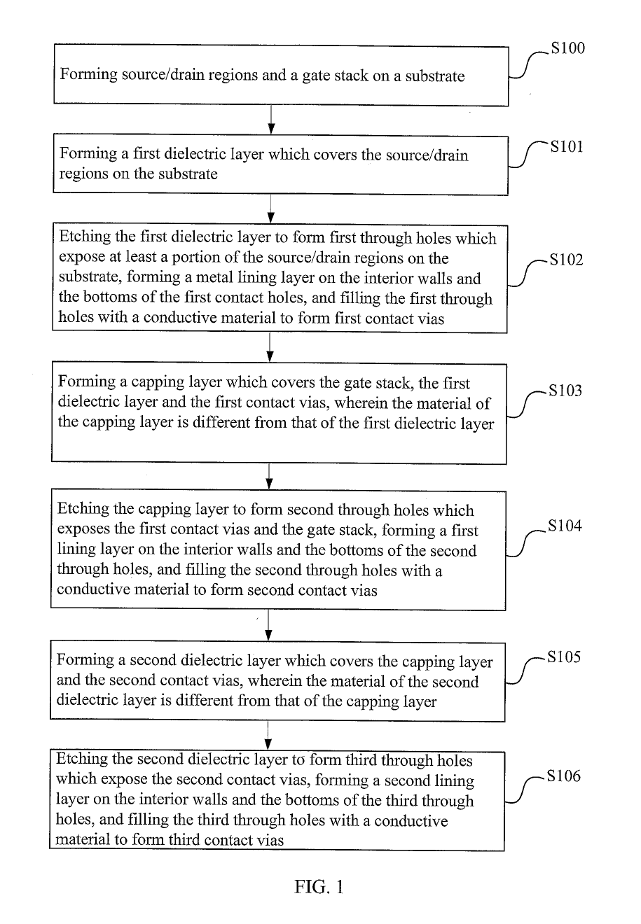

With reference to FIG. 1, the method comprises:

first, forming at least one gate stack and source/drain regions on a substrate, wherein the source/drain regions are located at both sides of the gate stack and are embedded in the substrate;

next, forming a first interlayer structure which comprises a first dielectric layer and a plurality of first contact vias, wherein the first dielectric layer is flushed with the gate stack or covers the gate stack, and the first contact vias penetrate through the first dielectric layer and are electrically connected with at least a portion of the source/drain regions;

then, forming a second interlayer structure which comprises a cap layer and a plurality of second contact vias, wherein the cap layer covers the first interlayer dielectric layer, and the second contact vias penetrate through the cap layer and are electrically connected with the first contact vias and the gate stack; and

finally, forming a third interlayer structure which comprises a second dielectric layer and a plurality of third contact vias, wherein the second dielectric layer covers the second interlayer structure, and the third contact vias penetrate through the second dielectric layer and are electrically connected with the second contact vias.

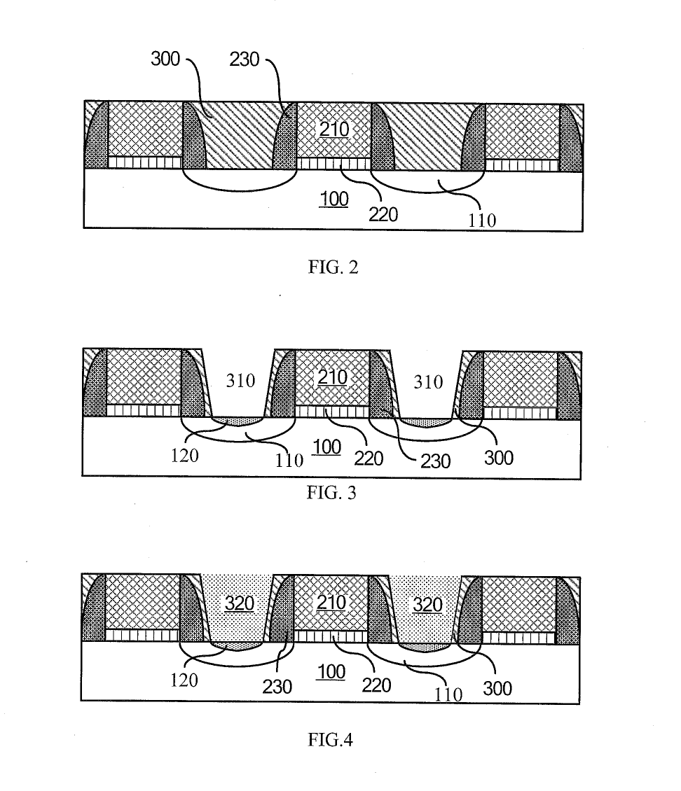

The foregoing steps are described here below with reference to FIG. 2 to FIG. 23.

With reference to FIG. 1 and FIG. 2, a first dielectric layer 300, which covers the source/drain regions 110, the gate stack and sidewall spacers 230, is formed on a substrate 100 (as shown in the figures, the first dielectric layer 300 also fills the space between the gate stacks). In the present embodiment, the substrate 100 includes a silicon substrate (e.g. silicon wafer). According to the widely known designing requirements in the prior art (e.g. a P-type substrate or an N-type substrate), the substrate may be of various doping configurations. Other examples of the substrate 100 may also include other basic semiconductors, for example, germanium. Alternatively, the substrate 100 may include compound semiconductors, such as Si:C, GaAs, InAs or InP. Typically, the substrate 100 may have, but not limited to, a thickness of about one hundred micrometer, which may, for example, be in the range of 400 μm-800 μm. All the following embodiments are illustrated with a silicon substrate.

The source/drain regions 110 may be formed by way of doping P-type or N-type dopants or impurities into the substrate 100. For example, for PMOS, the source/drain regions 110 may be consisted of P-type doped SiGe, whereas for NMOS, the source/drain regions 110 may be consisted of N-type doped Si. The source/drain regions 110 may be formed by means of lithography, ion implantation, diffusion and/or other process as appropriate, and may be formed prior to formation of a gate dielectric layer. In the present embodiment, the source/drain regions 110 are located within the substrate 100; in other embodiments, the source/drain regions 110 may be of a raised source/drain structure formed using a selective epitaxial growth method, wherein the top surface of the epitaxial portions is higher than the bottom of the gate stack (the expression “the bottom of the gate stack” herein refers to the interface between the gate stack and the substrate 100).

Optionally, the gate stack comprises a gate and a gate dielectric layer 220 carrying the gate in the Gate First process, and comprises a dummy gate and a gate dielectric layer 220 carrying the dummy gate in the Gate Last process. Particularly, sidewall spacers 230 are formed on the sidewalls of the gate stack in order to isolate the gates; the sidewall spacers 230 may be formed with Si₃N₄, SiO₂, SiON, Si:C or their combinations, and/or other materials as appropriate. The sidewall spacers 230 may be in a multi-layer structure. The sidewall spacers 230 may be formed by the processes including deposition and etching, and may be in a thickness of 10 nm-100 nm, for example, 30 nm, 50 nm or 80 nm.

The first dielectric layer 300 may be formed on the substrate 100 by means of Chemical Vapor Deposition (CVD), High Density Plasma CVD, or other methods as appropriate. The material of the first dielectric layer 300 may include doped or un-doped silicon glass, for example, FSG, BPSG, PSG, UGS, SiON, a low-k material or their combinations (e.g. the first dielectric layer 300 may be in a multi-layer structure, wherein the neighboring layers are made of different materials). The thickness of the first dielectric layer 300 may be in a range of 40 nm-150 nm, for example, 80 nm, 100 nm or 120 nm.

Next, the first dielectric layer 300 and the gate stack are planarized using Chemical-Mechanical Polish (CMP) method, such that the top surface of the gate stack and the top surface of the first dielectric layer 300 are in the same plane, and the top surface of the gate stack and the sidewall spacers 230 are exposed, as shown in FIG. 2. In case that the gate stack comprises a dummy gate, the gate replacement process may be implemented. Specifically, a dummy gate is removed first, then a metal gate layer is deposited into the recess formed from removal of the dummy gate, and then the metal gate layer is planarized such that its top surface shall be in the same plane as the first dielectric layer 300, thereby forming a gate metal 210. The gate dielectric layer 220 is located on the substrate 100 and it may be a thermal oxide layer including SiO₂ or SiON, or may be a high-k dielectric formed from deposition, for example, a material selected from a group consisting of HfO₂, FIfSiO, HfSiON, HfTaO, HMO, HfZrO, Al₂O₃, La₂O₃, ZrO₂, and LaAlO, or combinations thereof; the thickness of the gate dielectric layer 220 may be 2 nm-10 nm, for example, 5 nm or 8 nm. The gate metal 210 may be formed from a material selected from a group consisting of TaC, TiN, TaTbN, TaErN, TaYbN, TaSiN, HfSiN, MoSiN, RuTa and NiTa, or combinations thereof, and may be in a thickness of 10 nm-80 nm, for example, 30 nm or 50 nm. After the CMP process, the top surface of the gate stack is flushed with the top surface of the first dielectric layer 300.

With reference to FIG. 1, FIG. 3 and FIG. 4, the first dielectric layer 300 is etched to form a plurality of first through holes 310 which exposes at least a portion of the source/drain regions 110 on the substrate; a metal liner is formed on the interior walls and the bottom of the first through holes 310 (it is usually necessary to form a metal liner when the first through holes 310 has to be filled with W later; whereas it is not necessary to form a metal liner in the event that the first through holes 310 is to be filled with Al or TiAl alloy later; so are the cases of subsequent first liner and second liner, which is omitted herein); and then the first through holes 310 are filled with a conductive material to form a plurality of first contact vias 320. As shown in FIG. 3, specifically, the first dielectric layer 300 may be etched to form the first through holes 310 by using a dry etching method, wet etching method or other etching method as appropriate. Since the gate stack is protected by the sidewall spacers 230 and the material of the sidewall spacers 230 is usually different from the material of the first dielectric layer 300, no short circuit shall arise between the gate and the source/the drain, even if over-etching occurs when forming the first through holes 310. If the source/drain regions 110 are of raised source/drain structures formed using a selective epitaxial growth method, the top surface of the epitaxial portions is higher than the bottom of the gate stack, and thus the first through holes 310 may be formed inside the source/drain regions 110 to be flushed with the bottom of the gate stack. When forming first contact vias 320, the first contact vias 320 may come in contact with the source/drain regions 230 ascribing to its sidewalls near the bottom and its bottom, which thus further increases the contact area and reduces the contact resistance.

With reference to FIG. 4, a conductive material is filled into the first through holes 310 to form a plurality of first contact vias 320 by means of a deposition method. Preferably, the material of the first contact vias 320 is W. Of course, according to the requirements in manufacturing semiconductor structures, the material of the first contact vias 320 may be a material selected from a group consisting of W, Al and TiAl alloy, or combinations thereof. The first contact vias 320 are connected with the source/drain regions 110 and the first dielectric layer 300 or sidewall spacers 230 through a metal liner (not shown), which may be deposited on the interior walls and the bottom of the first through holes 310 by means of such deposition processes as ALD, CVD, PVD; and the material of the metal liner may be Ti, TiN, Ta, TaN, Ru or their combinations, and the thickness of the metal liner may be 5 nm-20 nm, for example, 10 nm or 15 nm.

Optionally, a contact layer (metal silicide 120) may be formed on the exposed source/drain regions 110 before the first contact vias 320 are formed. With reference to FIG. 3, the exposed source/drain regions lies below the first through holes 310; a metal is deposited on the source/drain regions 110 and then is annealed so as to form metal silicide 120. Specifically, first, pre-amorphization treatment is performed to the exposed source/drain regions via the first through holes 310 by means of amorphous compound deposition, ion implantation, or a selective growth method, so as to form a local amorphous silicon region; then, a uniform metal layer is formed on the source/drain regions 230 by using a metal sputtering process or a Chemical Vapor Deposition method; preferably, the metal may be Ni. Of course, the metal may also be other metals as appropriate, for example, Ti, Co or Cu, etc. Then, the semiconductor structure is annealed; in other embodiments, other annealing processes may be used, for example, rapid thermal annealing, spike annealing and the like. According to embodiments of the present invention, the devices are usually annealed by using a transient annealing process, for example, a laser annealing is performed at a temperature of about 1000° C. for a period of a micro second level, such that the deposited metal reacts with the amorphous compound formed within the source/drain regions 110 to form metal silicide 120; and finally, the deposited metal which remains from the reaction may be removed by using a chemical etching method. The amorphous compound may be amorphous silicon, amorphous SiGe or amorphous Si:C. The advantage of forming metal silicide 110 lies in its capability of reducing resistivity between the first contact vias 320 and the source/drain regions 110 so as to further reduce the contact resistance.

After formation of the first contact vias 320, a CMP process is performed to the first contact vias 320 and the first dielectric layer 300, such that the first contact vias 320 are flushed with the top surface of the first dielectric layer 300. In the present embodiment, the first contact vias 320 are flushed with the top surfaces of the first dielectric layer 300 and the gate metal 210; in other embodiments, the top surfaces of the first contact vias 320 and the first dielectric layer 300 may be higher than the top surface of the gate metal 210.

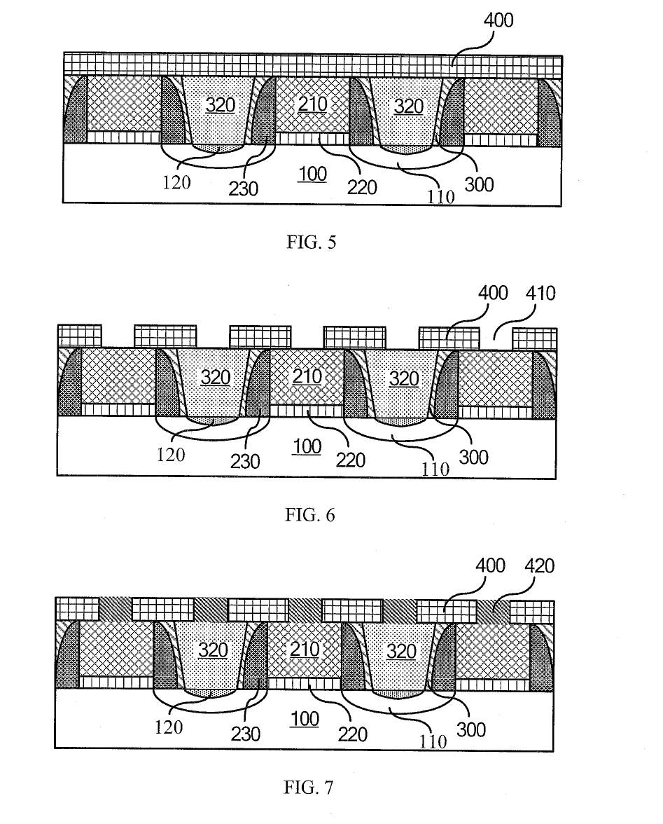

Next, a cap layer 400, which covers the gate stack, the first dielectric layer 300 and the first contact vias 320, is formed; the material of the cap layer 400 may be different from that of the first dielectric layer 300. With reference to FIG. 5, the cap layer 400 may be formed by means of Chemical Vapor Deposition (CVD), High Density Plasma CVD or other methods as appropriate. Preferably, the material of the cap layer 400 may be SiN or SiCN, or their combinations. However, it is necessary to make it clear that, the reason why the cap layer 400 and the first dielectric layer 300 are made of different materials is for implementation of selective etching so as to facilitate implementation of subsequent steps.

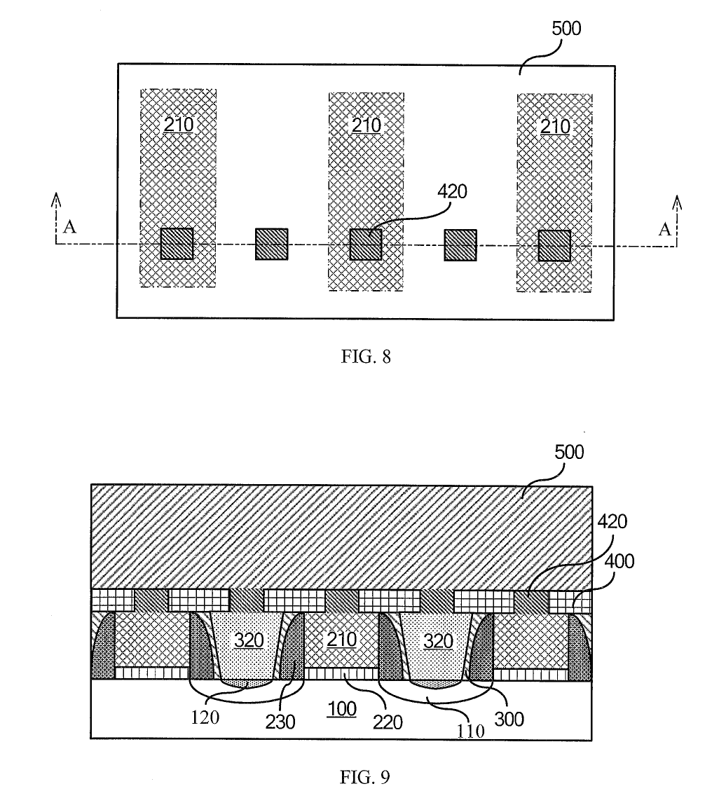

With reference to FIG. 1, FIG. 6 and FIG. 7, the cap layer 400 is etched to form a plurality of second through holes 410 which exposes the first contact vias 320 and the gate stack (for the embodiments where the top surfaces of the first contact vias 320 and the first dielectric layer 300 are higher than the top surface of the gate metal 210, in order to form a plurality of second through holes 410 which exposes the gate stack, the first dielectric layer 300 between the cap layer and the gate stack shall be etched as well for a certain thickness in addition to the etching of the cap layer 400). A first liner (not shown) is formed on the interior walls and the bottom of the second through holes 410, then a first conductive material is filled into the second through holes 410 to form a plurality of second contact vias 420, and then the planarization process is performed to the cap layer 400 and the second contact vias 420 so as to expose the top surface of the second contact vias 420, such that the top surface of the cap layer 400 and the top surface of the second contact vias 420 are in the same plane. It is applicable to form the second through holes 410 by means of dry etching or wet etching, etc. Preferably, at formation of the second through holes 410, the sidewalls of the second through holes 410 may be perpendicular to the top surface of the substrate 100.

Preferably, the material of the second contact vias 420 is Cu. Of course, according to the manufacturing requirements, the material of the second contact vias 420 may be a material selected from a group consisting of W, Al, Cu and TiAl, or combinations thereof.

After formation of the second contact vias 420, CMP planarization process is performed to the second contact vias 420 and the cap layer 400, such that the top surface of the second contact vias 420 are flushed with the top surface of the cap layer 400.

Preferably, at formation of the second through holes 410, the cross-sectional area of the second through holes 410 is made smaller than the cross-sectional area of the first through holes 310. Therefore, even if the positioning for etching to form the second through holes 410 is not very accurate, the corresponding second through holes 410 above the first contact vias 320 shall not be prone to deviate onto a neighboring gate region (which means the gate metal 210 in the present embodiment). As shown in FIG. 6, the inner diameter of the second through holes 410 is smaller than that of the first through holes 310. With such an arrangement, short circuits occurring between the gate and the source/drain at manufacturing of a semiconductor structure are effectively restrained. In order to alleviate the difficulty of etching the cap layer 400, the thickness of the cap layer 400 is made smaller than 30 nm, when forming the cap layer 400 or by implementing subsequent treatment to the cap layer 400. Since the thickness of the cap layer 400 is smaller than 30 nm, it becomes easy to control the etching of the cap layer 400, and thus it is not prone to cause damage to the gate due to over-etching.

Optionally, at least one of the second contact vias 420 is located on an active region of the substrate 100. In view of the manufacturing requirements, when forming certain second contact vias 420, it is also applicable to form portions thereof on an isolation region of the substrate 100. Preferably, the second contact vias 420 connected with the gate stack is formed on an active region of the substrate 100, whereas at least a portion of the second contact vias 420 connected with the first contact vias 320 is formed on an isolation region of the substrate 100, and such an arrangement is favorable for saving area.

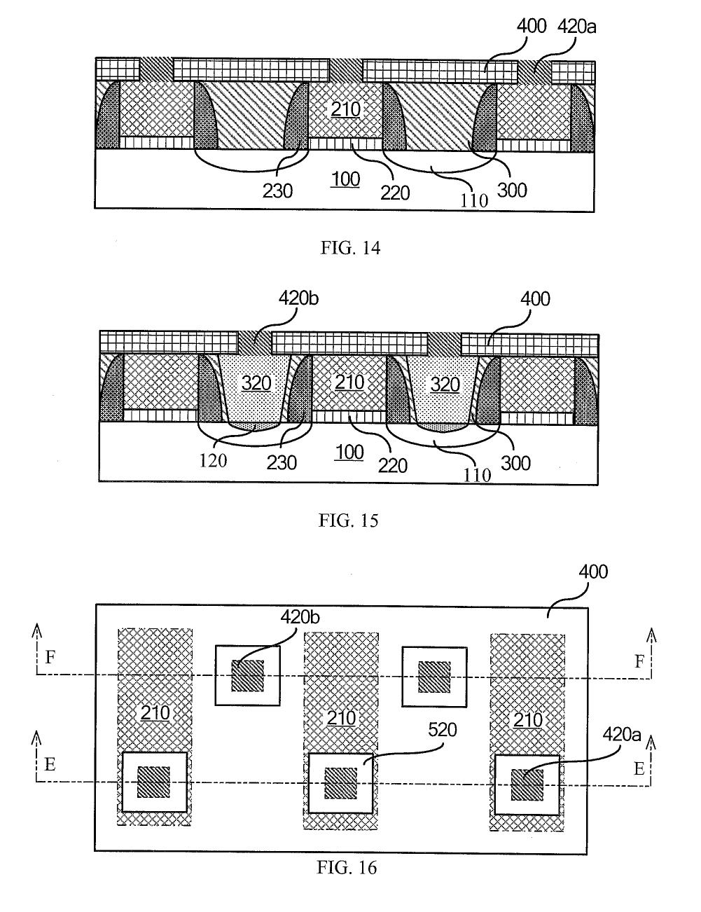

With reference to FIG. 8, the second contact vias 420 are positioned above the gate metal 210 and the source/drain regions 110, and the second contact vias 420 are substantially positioned on the same line. There may be additional arrangements in other embodiments, and will be described in detail with the embodiment illustrated in FIG. 14 to FIG. 23.

With reference to FIG. 1 and FIG. 9, a second dielectric layer 500, which covers the cap layer 400 and the second contact vias 420, is formed; the material of the second dielectric layer 500 is different from that of the cap layer 400. As shown in FIG. 9, the second dielectric layer 500 may be formed by means of Chemical Vapor Deposition (CVD), High Density Plasma CVD or other methods as appropriate. The materials for the cap layer and the second dielectric layer 500 may be selected from the same group of materials for the first dielectric layer 300, and thus are omitted herein. However, it should be noted that, in the present embodiment, the material of the second dielectric layer 500 is different from the material of the cap layer 400, in order to implement selective etching when forming third contact vias. Namely, the cap layer 400 is able to function as an etch stop layer when the second dielectric layer 500 is etched, so as to protect the gate stack and the first dielectric layer 300 under the cap layer 400.

Next, with reference to FIG. 1, FIG. 10 and FIG. 12, the second dielectric layer 500 is etched to form a plurality of third through holes 510 which expose the second contact vias 420. A second liner is formed at the interior sidewalls and the bottoms of the third through holes 510, and then a second conductive material is filled into the third through holes 510 to form a plurality of third contact vias 520. Then, the second dielectric layer 500 and the third contact vias 520 are planarized to expose the top surface of the third contact vias 520, such that the top surface of the second dielectric layer 500 and the top surface of the third contact vias 520 are on the same plane.

The third through holes 510 may be formed by means of dry etching or wet etching, etc.

Preferably, at formation of the third through holes 510, the sidewalls of the third through holes 510 may be made perpendicular to the top surface of the substrate 100.

With reference to FIG. 11, in the present embodiment, the third through holes 510 are positioned exactly above the second contact vias 420.

The formation methods, materials and thicknesses of the first liner and the second liner are the same as those of the metal liner, and thus are omitted herein.

Preferably, the material of the third contact vias 520 is Cu. Of course, according to the manufacturing requirements, the material of the third contact vias 520 may be a material selected from a group consisting of W, Al, Cu, and TiAl, or combinations thereof. Since the sidewalls of the second through holes 410 and the third through holes 510 are perpendicular to the top surface of the substrate 100, the sidewalls of the corresponding second contact vias 420 and the third contact vias 520 formed after filling the second through holes 410 and the third through holes 510 are also perpendicular to the top surface of the substrate 100.

After formation of the third contact vias 520, a CMP planarization process is performed to the third contact vias 520 and the second dielectric layer 500, such that the top surface of the third contact vias 520 is flushed with the top surface of the second dielectric layer 500.

Preferably, at formation of the third contact vias 510, the cross-sectional area of the third through holes 510 is made greater than the cross-sectional area of the second through holes 410, the cross-sectional area of the third through holes 510 is made as large as possible, and thus the cross-sectional area of the third contact vias 520 formed by filling the third through holes 510 will be large. The third contact vias 520 with a relatively large cross-sectional area is capable of reducing its own resistivity, which thus further reduces the resistance of the source/drain, thereby improving the performance of a semiconductor structure.

Preferably, because of the protection of the cap layer 400, there is no concern of damage to the lower portion of the second dielectric layer 500 because of over-etching occurring when the second dielectric layer 500 is etched. Therefore, the thickness of the second dielectric layer 500 may be selected to be greater than the thickness of the cap layer 400. Preferably, the thickness of the second dielectric layer 500 is greater than 50 nm. At the formation of the cap layer 400 and the second dielectric layer 500, the thickness of the cap layer 400 is usually made smaller than half of the thickness of the second dielectric layer 500. Such an arrangement is favorable for controlling the etching process.

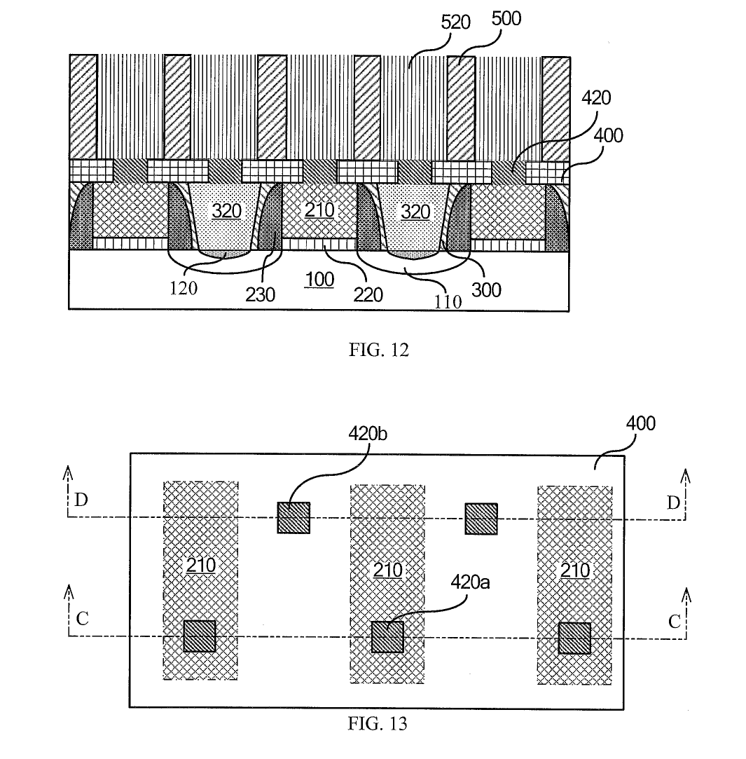

Optionally, the positions for forming the second contact vias 420 may be further arranged in other ways. With reference to FIG. 13, respective second contact vias 420 are not positioned on the same line. With further reference to FIG. 14 and FIG. 15, the second contact vias 420a electrically connected with the gate metal 210 are positioned on line C-C, while the second contact vias 420b electrically connected with the first contact vias 320 are positioned on line D-D. In the present embodiment, preferably, the second contact vias 420a electrically connected with the gate metal 210 is arranged away from the second contact vias 420b electrically connected with the source/drain regions 110 as far as possible (herein, the expression “away from . . . as far as possible” means to extend the distance between the second contact vias 420a and the second contact vias 420b in the prerequisite of ensuring normal performance of a semiconductor device and also saving the area. Preferably, the second contact vias 420a are positioned on an active region of the substrate 100, and portions of the second contact vias 420b are positioned on an isolation region of the substrate 100). The advantage of such an arrangement is to reduce capacitance between the gate and the source/drain, and also to restrain occurrence of short circuits between the gate and the source/drain, and even to facilitate the subsequent manufacturing.

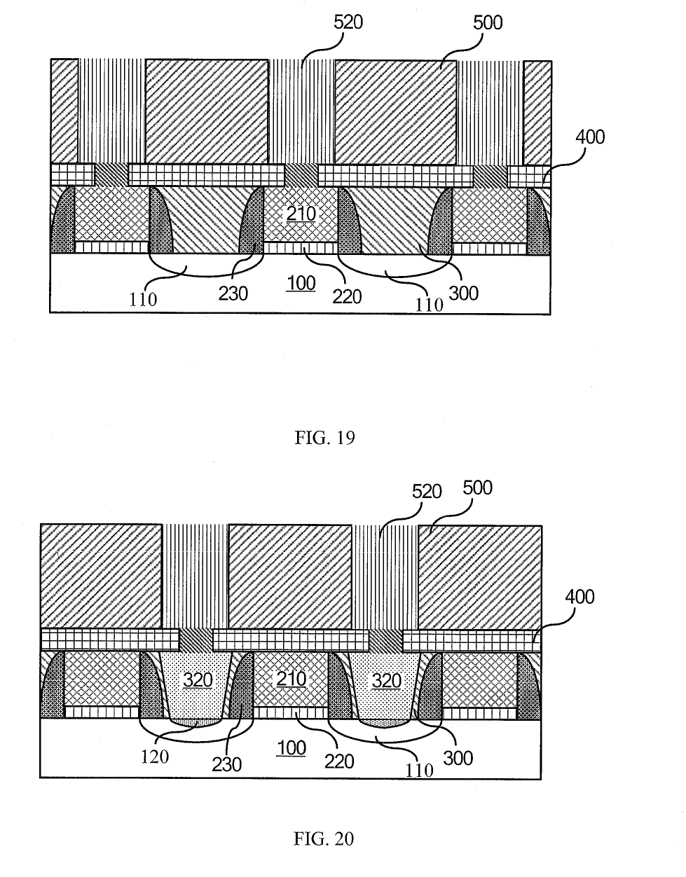

With reference to FIG. 16 and FIG. 18, a plurality of third through holes 510 are formed on the second contact vias 420, respectively. Accordingly, subsequent process may be performed to fill a second conductive material into the third through holes 510 to form a plurality of third contact vias 520, as shown in FIG. 19 and FIG. 20.

The advantage of the aforesaid arrangement lies in that the second contact vias 420a electrically connected with the gate stack shall be located far away from the second contact vias 420b electrically connected with the first contact vias 320, which, in one aspect, is favorable for reducing contact resistance between the second contact vias 420a and the second contact vias 420b when a metal interconnect layer is formed on the second dielectric layer 500 or at other places, and is also favorable for preventing short circuits from occurring between the gate and the source/drain, during subsequent processing of a semiconductor structure. In another aspect, the capacitance between the gate and the source/drain is reduced, and therefore the performance of the semiconductor structure is improved.

According to the method provided by the present invention, it is able to realize local electrical connection between source/drain and a gate, between gates or between source and drain at the cap layer 400. With reference to FIG. 21 and FIG. 22, at formation of second through holes 410, the area of the second through holes 410 is made relatively large. For example, the second through holes 410 may expose both the first contact vias 320 and the gate stack. Therefore, the second contact vias 420 formed by filling the second through holes 410 are electrically connected with both the gate metal 210 and the first contact vias 320. Namely, an electrical connection is established between the second contact vias 420 formed by filling the one or more second through holes(s) 410 and the exposed gate metal 210 and the first contact vias 320. However, it should be noted that the second through holes 410 which are able to expose both the first contact vias 320 and the gate stack may not be in the shape illustrated in the accompanying drawings, but may be in any other shape that is able to expose both the first contact vias 320 and the gate stack. Additionally, the local electrical connection between neighboring source/drain regions 110 may also be established by way of forming a second contact via 420 which is electrically connected with two neighboring first contact vias 320. It is also applicable to form the following structure, where at least one of the second contact vias 420 is electrically connected with at least one of the first contact vias 320 and the gate stack, and/or at least one of the second contact vias 420 is electrically connected with two or more of the first contact vias 320 and/or with the gate stack. Accordingly, it is easy to realize local connection between source/drain regions and a gate stack, between gates, or between a source region and a drain region in a semiconductor structure by controlling the shape and position of the second through holes 410.

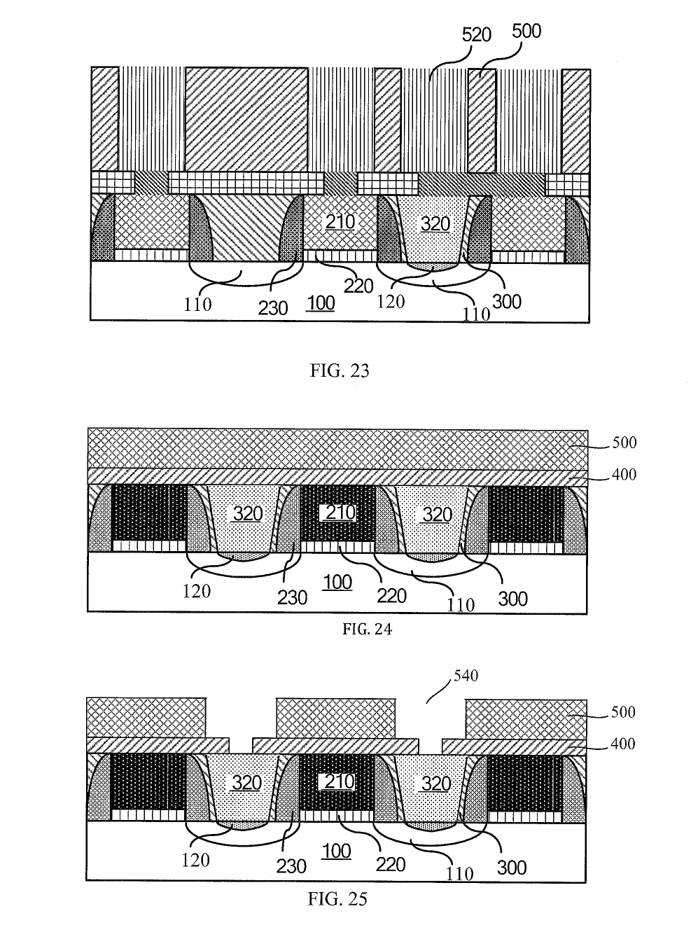

With reference to FIG. 23, third contact vias 520 are formed above the second contact vias 420, so as to facilitate the subsequent manufacturing of the semiconductor structure.

It should be noted that a semiconductor structure may include any one or any combination of aforesaid gate contact vias and source/drain region contact vias, according to manufacturing requirements of a semiconductor structure.

It is applicable to further form a plurality of first vias or a first metal wiring layer, wherein the first vias or the first metal wiring layer are electrically connected with the third contact vias 520 through a third liner. The materials, formation methods of the first vias, the first metal wiring layer and the third liner are the same as those described in foregoing embodiments, and thus are omitted herein.

Alternatively, a plurality of first vias are formed, and the first vias are electrically connected with the third contact vias 520. On the interfaces between the first vias and the third contact vias 520, the cross-sectional area of the first vias is smaller than the cross-sectional area of the third contact vias 520.

By forming first contact vias 320, second contact vias 420 and third contact vias 520 in three different layers, the implementation of the method for manufacturing a semiconductor structure provided by the present invention is capable of saving area, forming more semiconductor structures per unit area, and thereby improving integration density of semiconductor structures. Etching layer by layer is also favorable for reducing of short circuits between a contact metal and a gate arising from over-etching occurring at implementation of etching operations in the prior art. The difficulty in etching is also alleviated and the etching process becomes easy to control with formation of a cap layer 400 and a second dielectric layer 500. The reduction in cross-sectional area of the second through holes 420 makes etching not as difficult as before, such that short circuits are not prone to arise, even if the positioning at etching of the second hole 410 is not accurate. Since the cap layer 400 is thin, the height of the second contact vias 420 is relatively small, and even if the cross-sectional area of the second contact vias 420 is small, its resistance would not be great. By increasing the cross-sectional area of the third contact vias 520, and making the sidewalls of the third contact vias perpendicular to the top surface of the substrate, the contact resistance of the third contact vias 520 is reduced, which thus makes it possible that the total resistance of the third contact vias 520 and the second contact vias 420 is smaller than the resistance of the tapered contact metal mentioned in prior art. Because of the protection of the cap layer 400 to the gate stack, it is not prone to damage the gate stack or to cause short circuits between the gate and the source/drain regions at etching, even though the cross-sectional area of the third contact vias 520 is large or the positioning is not accurate. The second contact vias 420a connected with the gate stack is arranged away from the second contact vias 420b connected with the source/drain regions as far as possible, which facilitates subsequent processes, further restrains occurrence of short circuits between the source/drain regions and the gate, and further reduces the capacitance between the gate the source/the drain, so as to enhance the performance of a semiconductor structure. And it is applicable to form a local interconnect structure within the cap layer 400 by way of adjusting the shapes of the second through holes 410 and the second contact vias 420.

The present invention further provides a method for manufacturing a semiconductor structure comprising:

first, forming at least one gate stack and source/drain regions on a substrate, wherein the source/drain regions are located at both sides of the gate stack and are embedded in the substrate;

next, as shown in FIG. 4, forming a first interlayer structure which comprises a first dielectric layer 300 and first contact vias 320, wherein the first dielectric layer 300 is flushed with the gate stack or covers the gate stack, and the first contact vias 320 penetrate through the first dielectric layer 300 and are electrically connected with at least a portion of the source/drain regions 110;

wherein, the step for forming the first contact vias 320 comprises:

forming first through holes in the first dielectric layer 300 to expose at least a portion of the source/drain regions 110;

forming a contact layer (e.g. a metal silicide layer 120) on the exposed source/drain region 110; and

forming a conductive material on the contact layer to fill the first through holes.

Then, a fourth interlayer structure is formed. The fourth interlayer structure comprises a cap layer, a second dielectric layer and a plurality of fourth contact vias. The cap layer covers the first interlayer structure, the second dielectric layer covers the cap layer, and the fourth contact vias penetrate through the cap layer and the second dielectric layer and are electrically connected with the first contact vias and the gate stack. The cross-sectional area of the fourth contact vias embedded within the cap layer is smaller than the cross-sectional area of the first contact vias and/or the cross-sectional area of the fourth contact vias embedded within the second dielectric layer.

The step for forming the first interlayer structure is the same as that provided in the foregoing embodiments, and thus is omitted herein.

The steps for forming the fourth interlayer structure comprise:

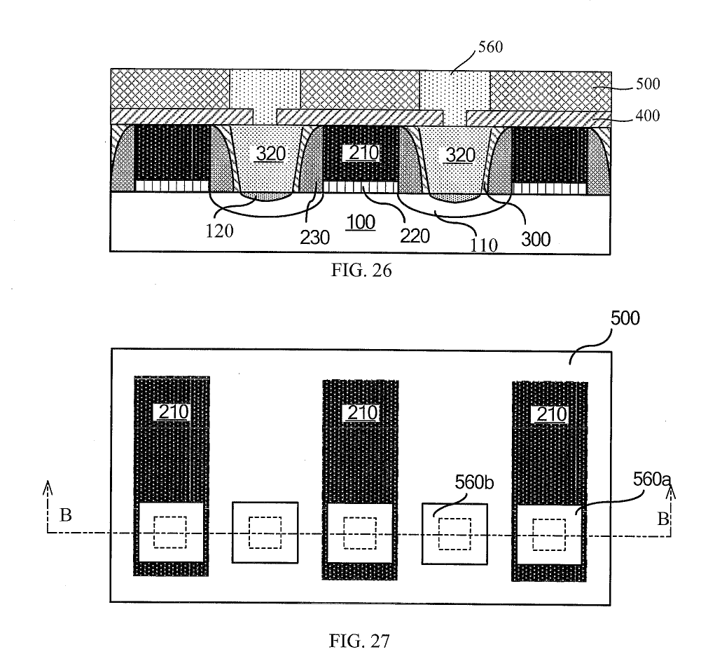

first, as shown in FIG. 24, forming a cap layer 400 and a second dielectric layer 500; next, as shown in FIG. 25, forming a plurality of fourth through holes 540 in the cap layer 400 and the second dielectric layer 500 by means of a dual Damascene process, wherein, at the interface between the cap layer and the second dielectric layer, the cross-sectional area of the fourth through holes 540 embedded within the cap layer 400 is smaller than the cross-sectional area of the first contact vias 320 and (in the present embodiment)/or the cross-sectional area of the fourth through holes 540 embedded within the second dielectric layer 500 (herein, the term “cross-sectional area” means a cross-section resulted from cutting by a plane parallel to the top surface of the substrate 100 in any spatial dimension, for example, in the fourth through holes embedded within the second dielectric layer 500), as shown in FIG. 25, the cross-sectional area of the fourth through holes 540 at the interface between the cap layer and the second dielectric layer having a stepped change; and then, filling the fourth through holes 540 with a fourth conductive material to form a plurality of fourth contact vias 560, wherein, when the fourth conductive material is Cu, a fourth liner may be formed in advance to cover the bottoms and sidewalls of the fourth through holes 540 before formation of the fourth conductive material, and if the fourth conductive material is a material selected from a group consisting of W, Al and TiAl, or combinations thereof, the fourth liner may not be formed in advance. The material and the formation method of the fourth liner are the same as those of the first liner and the second liner, and are omitted herein. After formation of the fourth contact vias 560, a CMP process may be performed to expose the second dielectric layer 500, so as to obtain a semiconductor structure illustrated in FIG. 26. As shown in FIG. 27, the fourth contact vias 560a electrically connected with the gate stack and its neighboring fourth contact vias 560b electrically connected with the first contact vias may be on the same line.

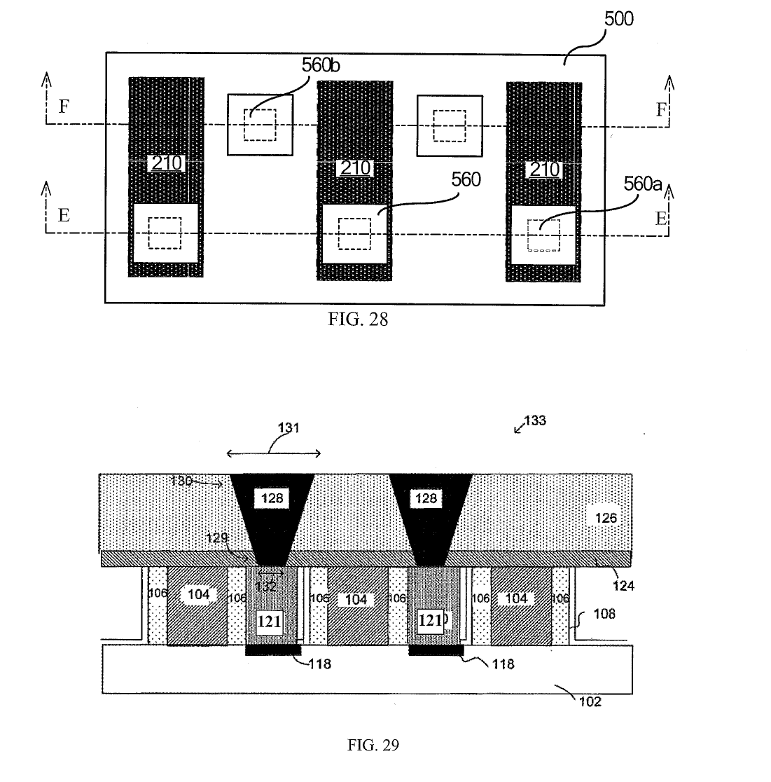

Particularly, as shown in FIG. 28, at formation of the fourth contact vias 560, at least one of the fourth contact vias 560a electrically connected with the gate stack may not be aligned with its neighboring fourth contact vias 560b electrically connected with the first contact vias. And/or, at formation of the fourth contact vias 560, the fourth contact vias 560a electrically connected with the gate stacks are formed on an active region of the substrate; and/or, at formation of the fourth contact vias 560, portions of the fourth contact vias 560b electrically connected with the first contact vias are formed on an isolation region of the substrate.

Optionally, the sidewalls of the fourth contact vias 560 may be perpendicular to the top surface of the substrate. Optionally, the thickness of the cap layer 400 is smaller than half of the thickness of the second dielectric layer 500. Optionally, the material of the cap layer 400 may be different from the material of the first dielectric layer 300 and the second dielectric layer 500, and the material of the cap layer 400 is an insulating material. Optionally, the thickness of the cap layer is smaller than 30 nm; and/or, the thickness of the second dielectric layer 500 may be greater than 50 nm.

The present invention further provides a semiconductor structure, comprising:

at least one gate stack and source/drain regions, wherein the gate stack is formed on a substrate, and the source/drain regions are located at both sides of the gate stack and are embedded in the substrate;

a first interlayer structure which comprises a first dielectric layer and a plurality of first contact vias, wherein the first dielectric layer is flushed with the gate stack or covers the gate stack, and the first contact vias penetrate through the first dielectric layer and are electrically connected with at least a portion of the source/drain regions; and

a fourth interlayer structure which comprises a cap layer, a second dielectric layer and a plurality of fourth contact vias; the cap layer covers the first interlayer structure, the second dielectric layer covers the cap layer, and the fourth contact vias penetrate through the cap layer and the second dielectric layer and are electrically connected with the first contact vias and the gate stack; and at the interface between the cap layer and the second dielectric layer, the cross-sectional area of the fourth contact vias embedded within the cap layer is smaller than the cross-sectional area of the first contact vias and/or the cross-sectional area of the fourth contact vias embedded within the second dielectric layer.

The semiconductor structure may further comprise a contact layer which is formed only between the source/drain and the first contact vias.

At least one of the fourth contact vias electrically connected with the gate stack is not aligned with its neighboring fourth contact vias electrically connected with the first contact vias. Optionally, the fourth contact vias electrically connected with the gate stacks are formed on an active region of the substrate; and/or, portions of the fourth contact vias electrically connected with the first contact vias are formed on an isolation region of the substrate.

Optionally, the sidewalls of the fourth contact vias may be perpendicular to the top surface of the substrate. Optionally, the thickness of the cap layer may be smaller than half of the thickness of the second dielectric layer. Optionally, the material of the cap layer may be different from the material of the first dielectric layer and the second dielectric layer, and the material of the cap layer may be an insulating material. Optionally, the thickness of the cap layer may be smaller than 30 nm; and/or, the thickness of the second dielectric layer may be greater than 50 nm. Particularly, the fourth contact vias may be electrically connected with the first contact vias and/or the gate stack through a fourth liner.

Although the exemplary embodiments and their advantages have been described in detail, it should be understood than any/various alternations, substitutions and modifications may be made to the embodiments without departing from the spirit of the present invention and the scope as defined by the appended claims. For other examples, it may be easily recognized by a person of ordinary skill in the art that the order of the process steps may be changed without departing from the scope of the present invention.

In addition, the scope to which the present invention is applied is not limited to the process, mechanism, manufacture, material composition, means, methods and steps described in the specific embodiments in the specification. A person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A method for manufacturing a semiconductor structure, comprising:
a) forming at least one gate stack and respective source/drain regions on a substrate, wherein the source/drain regions are located at both sides of the gate stack and are embedded in the substrate;
b) forming a first interlayer structure which comprises a first dielectric layer and a plurality of first contact vias, wherein the first dielectric layer is flushed with the gate stack or covers the gate stack, and the first contact vias penetrate through the first dielectric layer and are electrically connected with at least a portion of respective source/drain regions;
c) forming a second interlayer structure which comprises a cap layer and a plurality of second contact vias, wherein the cap layer covers the first interlayer structure, and the second contact vias penetrate through the cap layer and are electrically connected with respective first contact vias and gate stacks; and
d) forming a third interlayer structure which comprises a second dielectric layer and a plurality of third contact vias, wherein the second dielectric layer covers the second interlayer structure, and the third contact vias penetrates through the second dielectric layer and are electrically connected with the second contact via.

2. The method according to claim 1, wherein the step for forming the first contact vias comprises:
forming a plurality of first through holes within the first dielectric layer to expose at least a portion of the source/drain regions;
forming a contact layer on the exposed source/drain regions; and
forming a conductive material on the contact layer to fill the first through holes.

3. The method according to claim 1, wherein:
the cross-sectional area of the second contact vias are smaller than the cross-sectional area of the first contact vias and/or the cross-sectional area of the third contact vias.

4. The method according to claim 1, wherein:
at least one of the second contact vias electrically connected with the gate stack is not aligned with neighboring second contact vias electrically connected with respective first contact vias.

5. The method according to claim 1, wherein:
the second contact vias electrically connected with respective gate stacks are formed on respective active regions of the substrate; and/or
a portion of each of the second contact vias electrically connected with the first contact via is formed on an isolation region of the substrate.

6. The method according to claim 1, wherein:
sidewalls of the second contact vias or the third contact vias are perpendicular to the top surface of the substrate.

7. The method according to claim 1, wherein
the thickness of the cap layer is smaller than half of the thickness of the second dielectric layer.

8. The method according to claim 1, wherein:
the material of the cap layer is different from the materials of the first dielectric layer and the second dielectric layer, and the material of the cap layer is an insulating material.

9. The method according to claim 1, wherein:
the thickness of the cap layer is smaller than 30 nm; and/or
the thickness of the second dielectric layer is greater than 50 nm.

10. The method according to claim 1, wherein:
the second contact vias are electrically connected with respective first contact vias and gate stacks through a first liner; and/or
the third contact vias are electrically connected with respective second contact vias through a second liner.

11. The method according to claim 1, further comprising:
forming a plurality of first vias or a first metal wiring layer, wherein the first vias or the first metal wiring layer are electrically connected with respective third contact vias through a third liner.

12. The method according to claim 1, further comprising:
forming a plurality of first vias, wherein the first vias are electrically connected with respective third contact vias, and wherein the cross-sectional area of the first vias is smaller than the cross-sectional area of the third contact vias at the interface between the first vias and the third contact vias.

13. The method according to claim 1, wherein:
at least one of the second contact vias formed in step c) is electrically connected with at least one of the first contact vias and with the gate stack; and/or
at least one of the second contact vias is electrically connected with two or more of the first contact vias and/or with two or more of the gate stacks.

14. A semiconductor structure, comprising:
at least one gate stack formed on a substrate;
source/drain regions located at both sides of the gate stack and embedded in the substrate;
a first interlayer structure which comprises a first dielectric layer and a plurality of first contact vias, wherein the first dielectric layer is flushed with the gate stack or covers the gate stack, and the first contact vias penetrate through the first dielectric layer and are electrically connected with a portion of respective source/drain regions;
a second interlayer structure which comprises a cap layer and a plurality of second contact vias, wherein the cap layer covers the first interlayer structure, and the second contact vias penetrate through the cap layer and are electrically connected with respective first contact vias and gate stacks; and
a third interlayer structure which comprises a second dielectric layer and a plurality of third contact vias, wherein the third dielectric layer covers the second interlayer structure, and the third contact vias penetrate through the second dielectric layer and are electrically connected with respective second contact vias through a second liner.

15. The semiconductor structure according to claim 14, further comprising a contact layer which is formed between the source/drain regions and the first contact vias.

16. The semiconductor structure according to claim 14, wherein:
the cross-sectional area of the second contact vias is smaller than the cross-sectional area of the first contact vias and/or the cross-sectional area of the third contact vias.

17. The semiconductor structure according to claim 14, wherein:
at least one of the second contact vias electrically connected with the gate stack is not aligned with neighboring second contact vias electrically connected with respective first contact vias.

18. The semiconductor structure according to claim 14, wherein:
the second contact vias electrically connected with the gate stack are formed on respective active regions of the substrate; and/or
a portion of each the second contact vias electrically connected with respective first contact vias is formed on an isolation region of the substrate.

19. The semiconductor structure according to claim 14, wherein:
sidewalls of the second contact vias or the third contact vias are perpendicular to the top surface of the substrate.

20. The semiconductor structure according to claim 14, wherein:
the thickness of the cap layer is smaller than half of the thickness of the second dielectric layer.

21. The semiconductor structure according to claim 14, wherein:
the material of the cap layer is different from the material of the first dielectric layer and the second dielectric layer, and the material of the cap layer is an insulating material.

22. The semiconductor structure according to claim 14, wherein:
the thickness of the cap layer is smaller than 30 nm; and/or
the thickness of the second dielectric layer is greater than 50 nm.

23. The semiconductor structure according to claim 14, further comprising:
a plurality of first vias or a first metal wiring layer, wherein the first vias or the first metal wiring layer are electrically connected with respective third contact vias through a third liner.

24. The semiconductor structure according to claim 14, further comprising a plurality of first vias, wherein the first vias are electrically connected with respective third contact vias, and wherein on the interface between the first vias and the third contact vias, the cross-sectional area of the first vias is smaller than the cross-sectional area of the third contact vias.

25. The semiconductor structure according to claim 14, wherein:
at least one of the second contact vias is electrically connected with at least one of the first contact vias and with the gate stack; and/or
at least one of the second contact vias is electrically connected with two or more of the first contact vias and/or with two or more of the gate stacks.

26. A semiconductor structure, comprising:
at least one gate stack formed on a substrate;
source/drain regions located at both sides of the gate stack and embedded in the substrate;
a first interlayer structure which comprises a first dielectric layer and a plurality of first contact vias, wherein the first dielectric layer is flushed with the gate stack or covers the gate stack, and the first contact vias penetrate through the first dielectric layer and are electrically connected with at least a portion of respective source/drain regions;
a second interlayer structure which comprises a cap layer and a plurality of second contact vias, wherein the cap layer covers the first interlayer structure, and the second contact vias penetrate through the cap layer and are electrically connected with respective first contact vias and gate stacks; and
a third interlayer structure which comprises a second dielectric layer and a plurality of third contact vias, wherein the second dielectric layer covers the second interlayer structure, and the third contact vias penetrate through the second dielectric layer and are electrically connected with respective second contact vias, and the cross-sectional area of the second contact vias is smaller than the cross-sectional area of the first contact vias and/or the cross sectional area of the third contact vias.

27. The semiconductor structure according to claim 26, further comprising a contact layer which is formed between the source/drain regions and the first contact vias.

28. The semiconductor structure according to claim 26, wherein:
at least one of the second contact vias electrically connected with the gate stack is not aligned with neighboring second contact vias electrically connected with respective first contact vias.

29. The semiconductor structure according to claim 26, wherein:
the second contact vias electrically connected with respective gate stacks are formed on respective active regions of the substrate; and/or
a portion of each of the second contact vias electrically connected with respective first contact vias is formed on an isolation region of the substrate.

30. The semiconductor structure according to claim 26, wherein:
the sidewalls of the second contact vias or the third contact vias are perpendicular to the top surface of the substrate.

31. The semiconductor structure according to claim 26, wherein:
the thickness of the cap layer is smaller than half of the thickness of the second dielectric layer.

32. The semiconductor structure according to claim 26, wherein:
the material of the cap layer is different from the material of the first dielectric layer and the second dielectric layer, and the material of the cap layer is an insulating material.

33. The semiconductor structure according to claim 26, wherein:
the thickness of the cap layer is smaller than 30 nm; and/or
the thickness of the second dielectric layer is greater than 50 nm.

34. The semiconductor structure according to claim 26, wherein:
at least one of the second contact vias are electrically connected with at least one of the first contact vias and with the gate stack; and/or
at least one of the second contact vias are electrically connected with two or more of the first contact vias and/or with two or more of the gate stacks.

35. A method for manufacturing a semiconductor structure, comprising:
a) forming at least one gate stack and source/drain regions on a substrate, wherein the source/drain regions are located at both sides of the gate stack and are embedded in the substrate;
b) forming a first interlayer structure which comprises a first dielectric layer and a plurality of first contact vias; wherein the first dielectric layer is flushed with the gate stack or covers the gate stack, and the first contact vias penetrate through the first dielectric layer and are electrically connected with at least a portion of the source/drain regions; and
c) forming a fourth interlayer structure which comprises a cap layer, a second dielectric layer and a plurality of fourth contact vias, wherein the cap layer covers the first interlayer structure, the second dielectric layer covers the cap layer, and the fourth contact vias penetrate through the cap layer and the second dielectric layer and are electrically connected with respective first contact vias and gate stacks, and on the interface between the cap layer and the second dielectric layer, the cross-sectional area of the fourth contact vias embedded within the cap layer is smaller than the cross-sectional area of the first contact vias and/or the cross-sectional area of the fourth contact vias embedded within the second dielectric layer.

36. The method according to claim 35, wherein the step for forming first contact vias comprises:
forming a plurality of first through holes within the first contact dielectric layer to expose at least a portion of each of respective source/drain regions;
forming a contact layer on the exposed source/drain region; and
forming a conductive material on the contact layer to fill the first through holes.

37. The method according to claim 35, wherein:
at least one of the fourth contact vias electrically connected with the gate stack is not aligned with neighboring fourth contact vias electrically connected with respective first contact vias.

38. The method according to claim 35, wherein:
the fourth contact vias electrically connected with respective gate stacks are formed on active regions of the substrate; and/or
a portion of each of the fourth contact vias electrically connected with respective first contact vias is formed on an isolation region of the substrate.

39. The method according to claim 35, wherein:
the sidewalls of the fourth contact vias are perpendicular to the top surface of the substrate.

40. The method according to claim 35, wherein:
the thickness of the cap layer is smaller than half of the thickness of the second dielectric layer.

41. The method according to claim 35, wherein:
the material of the cap layer is different from the material of the first dielectric layer and the second dielectric layer, and the material of the cap layer is an insulating material.

42. The method according to claim 35, wherein:
the thickness of the cap layer is smaller than 30 nm; and/or
the thickness of the second dielectric layer is greater than 50 nm.

43. The method according to claim 35, wherein:
the fourth contact vias are electrically connected with respective first contact vias and/or gate stacks through a fourth liner.

44. A semiconductor structure comprising:
at least one gate stack and source/drain regions, wherein the gate stack is formed on a substrate, and the source/drain regions are located at both side of the gate stack and are embedded in the substrate;
a first interlayer structure which comprises a first dielectric layer and a plurality of first contact vias, wherein the first dielectric layer is flushed with the gate stack or covers the gate stack, and the first contact vias penetrate through the first dielectric layer and are electrically connected with at least a portion of respective source/drain regions; and
a fourth interlayer structure which comprises a cap layer, a second dielectric layer and a plurality of fourth contact vias, wherein the cap layer covers the first interlayer structure, the second dielectric layer covers the cap layer, and the fourth contact vias penetrate through the cap layer and the second dielectric layer and are electrically connected with respective first contact vias and gate stacks, and on the interface between the cap layer and the second dielectric layer, the cross-sectional area of the fourth contact vias embedded within the cap layer is smaller than the cross-sectional area of the first contact vias and/or the cross-sectional area of the fourth contact vias embedded within the second dielectric layer.

45. The semiconductor structure according to claim 44, further comprising a contact layer which is formed between the source/drain regions and the first contact vias.

46. The semiconductor structure according to claim 44, wherein:
at least one of the fourth contact vias electrically connected with respective gate stacks is not aligned with neighboring fourth contact vias electrically connected with respective first contact vias.

47. The semiconductor structure according to claim 44, wherein:
the fourth contact vias electrically connected with respective gate stacks are formed on active regions of the substrate; and/or
a portion of each of the fourth contact vias electrically connected with respective first contact vias is formed on an isolation region of the substrate.

48. The semiconductor structure according to claim 44, wherein:
the sidewalls of the fourth contact vias are perpendicular to the top surface of the substrate.

49. The semiconductor structure according to claim 44, wherein:
the thickness of the cap layer is smaller than half of the thickness of the second dielectric layer.

50. The semiconductor structure according to claim 44, wherein:
the material of the cap layer is different from the material of the first dielectric layer and the second dielectric layer, and the material of the cap layer is an insulating material.

51. The semiconductor structure according to claim 44, wherein
the thickness of the cap layer is smaller than 30 nm; and/or
the thickness of the second dielectric layer is greater than 50 nm.

52. The semiconductor structure according to claim 44, wherein:
the fourth contact vias are electrically connected with respective first contact vias and/or gate stacks through a fourth liner.
